(19) United States
(12) Patent Application Publication
(10) Pub. No.: US 2011/0169061 A1
(43) Pub. Date: Jul. 14, 2011

(54) Semiconductor device and method for manufacturing the same

(75) Inventors: Mitsunari Sukekawa, Tokyo (JP); Keisuke Otsuka, Tokyo (JP)

(73) Assignee: Elpida Memory, Inc., Tokyo (JP)

(21) Appl. No.: 12/926,559

(22) Filed: Nov. 24, 2010

(30) Foreign Application Priority Data
Jan. 12, 2010 (JP) 2010-003976

(51) Int. Cl. H01L 27/108; H01L 21/8242

(52) U.S. Cl. 257/296; 438/253; 257/E21.646; 257/E27.084

(57) ABSTRACT

The semiconductor device comprises a first region, a guard ring surrounding the first region, and a second region outside of the guard ring. The first region includes a first electrode made of a first film which has conductivity. A surface of the first electrode in the first region is not covered with the second film. The guard ring includes the first film covering an inner wall of a groove having a recess shape, and a second film as an insulating film covering at least one portion of a surface of the first film in the groove.

This application is based upon and claims the benefit of priority from Japanese Patent Application No. 2010-003976, filed on Jan. 12, 2010, the disclosure of which is incorporated herein in its entirety by reference.

### BACKGROUND OF THE INVENTION

1. Technical Field

The invention relates to a semiconductor device and a method for manufacturing the same.

2. Related Art

As a miniaturization of semiconductor device proceeds, an area of a memory cell constituting DRAM (Dynamic Random Access Memory) device reduces. In order to secure sufficient capacitance in a capacitor constituting the memory cell, it is common that the capacitor is formed as a 3-dimensional structure. Speaking specifically, as disclosed in Japanese patent Laid-Open No. 1995-007084, a lower electrode is formed so as to have a cylinder shape, and side surface of the lower electrode is used as a part of the capacitor, to make it possible to enlarge effective surface area of the electrode.

Further, as the area of the memory cell reduces, an area of a bottom of a lower electrode of the capacitor gets smaller. For this reason, as in Japanese patent Laid-Open Nos. 2003-297952 and 2008-283026, a supporting film is disposed between the lower electrodes so as to support them. In Japanese patent Laid-Open Nos. 2003-297952 and 2008-283026, this supporting film prevents the lower electrodes from collapsing and then forming a short circuit with neighboring lower electrodes during the process of exposing outer walls of the lower electrodes of the capacitor using wet etching.

In the process of exposing the outer walls of the lower electrodes of the capacitor using the wet etching, it is necessary to prevent etchant for the wet etching from invading in the region which the capacitor is not formed. For this reason, a groove pattern is formed at an outer periphery of the memory cell region including the capacitor, and, then, a guard ring is formed by covering an inner wall of the groove pattern with the lower electrode material at the same time as in forming the lower electrodes.

### SUMMARY OF THE INVENTION

In one embodiment, there is provided a semiconductor device, comprising:

a first region;

a guard ring surrounding the first region; and

a second region outside of the guard ring,

wherein the first region comprises a first electrode made of a first film which has conductivity,

wherein the guard ring comprises the first film covering an inner wall of a groove having a recess shape, and a second film as an insulating film covering at least one portion of a surface of the first film in the groove, and

wherein a surface of the first electrode in the first region is not covered with the second film.

In another embodiment, there is provided a method for manufacturing a semiconductor device, comprising;

providing a structure comprising a semiconductor substrate, an interlayer insulating film, and a supporting film in this order, the structure including a first region, a second region surrounding the first region, and a boundary between the first and second regions;

forming a groove having a recess shape, the groove including an inner wall covered with a first film having conductivity, in the interlayer insulating film positioned in the boundary;

forming a fifth film as an insulating film in the first and second regions and the groove so that an upper portion of the groove is not blocked with the fifth film;

forming a second film as an insulating film in the first and second regions and the groove so as to cover a surface of the fifth film in the first and second regions and the groove and cover a surface of the first film exposed in the groove;

removing the second film so that the second film remains only in the groove; and

removing the interlayer insulating film in the first region using wet etching.

### BRIEF DESCRIPTION OF THE DRAWINGS

The above features and advantages of the present invention will be more apparent from the following description of certain preferred embodiments taken in conjunction with the accompanying drawings, in which:

FIG. 1 illustrates one exemplary embodiment of a semiconductor device according to the invention;

FIG. 2 illustrates one exemplary embodiment of the semiconductor device according to the invention;

FIG. 3 illustrates one exemplary embodiment of the semiconductor device according to the invention;

FIG. 4 illustrates one exemplary embodiment of the semiconductor device according to the invention;

FIGS. 5A and 5B illustrate one process of a method for manufacturing a semiconductor device according to the invention;

FIGS. 6A and 6B illustrate one process of a method for manufacturing a semiconductor device according to the invention;

FIGS. 7A and 7B illustrate one process of a method for manufacturing a semiconductor device according to the invention;

FIG. 8 illustrates one process of the method for manufacturing the semiconductor device according to the invention;

FIG. 9 illustrates one process of the method for manufacturing the semiconductor device according to the invention;

FIG. 10 illustrates one process of the method for manufacturing the semiconductor device according to the invention;

FIG. 11 illustrates one process of the method for manufacturing the semiconductor device according to the invention;

FIG. 12 illustrates one process of the method for manufacturing the semiconductor device according to the invention;

FIG. 13 illustrates one process of the method for manufacturing the semiconductor device according to the invention;

FIG. 14 illustrates one process of the method for manufacturing the semiconductor device according to the invention;

FIG. 15 illustrates one process of the method for manufacturing the semiconductor device according to the invention; and

FIG. 16 illustrates one process of the method for manufacturing the semiconductor device according to the invention.

In the drawings, numerals have the following meanings. 1: semiconductor device, 3: isolation region, 4: first interlayer insulating film. 4A: bit line contact plug, 5: gate electrode, 5a: gate insulating film, 5b: side wall, 5c: protection film, 6: bit wire, 7: second interlayer insulating film, 7A: capacitive contact plug, 8: source/drain regions, 9: substrate contact plug, 10: capacitive contact pad, 11: third interlayer insulating film, 12: fourth interlayer insulating film, 12A: opening, 12B: guard ring, 13: lower electrode, 14: supporting film, 14A: opening, 15: upper electrode, 16: capacitive insulating film, 17: photoresist film, 20: fifth interlayer insulating film, 21: metal interconnection layer, 22: surface protection film, 25: contact plug, 30: capacitor, 31: first silicon nitride film, 32: second silicon nitride film, 33: cavity, 34: photoresist film, 35: mask pattern, 40: gate interlayer insulating film, 50: DRAM device, 51: memory cell region, 52: peripheral circuit region, 205a, 205b, 205c: positions of substrate contact plugs, K: active region, Trl: MOS transistor, W: word wire

### DETAILED DESCRIPTION OF EXEMPLARY EMBODIMENTS

A second film is, in advance, formed on an inner side wall of an upper portion of a guard ring groove having a recess shape. As a result, the second film effectively prevents the etchant from invading a second region through the guard ring, during a subsequent wet etching process for removing an interlayer insulating film in a first region. In this way, it is possible to provide the semiconductor device with high performance and without deterioration of the second region characteristics resulting from the invasion of the etchant. Further, the second film is not formed on a surface of a first electrode in the first region. In this way, characteristics deterioration of device including the first electrode in the first region may be avoided.

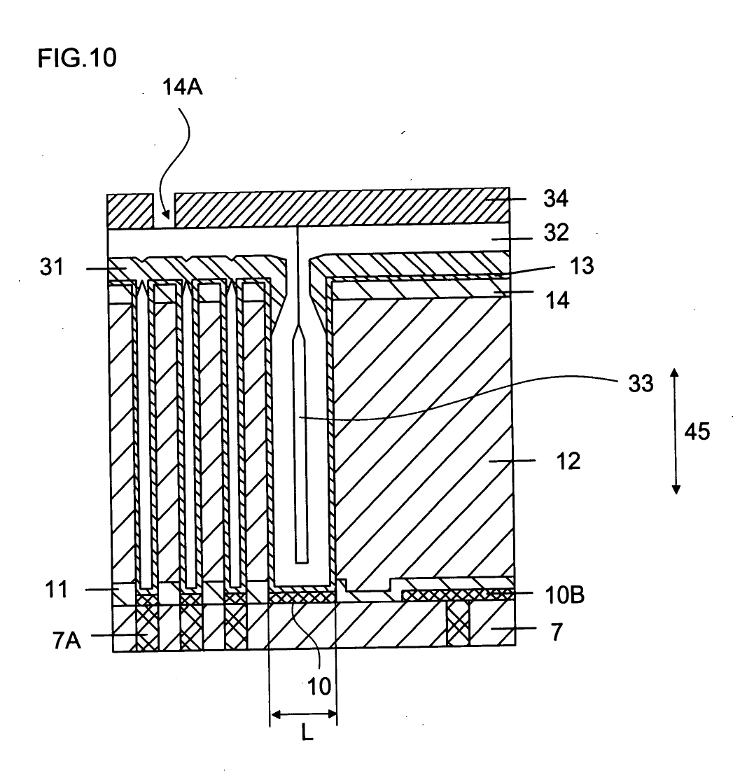

In this specification and claims, “an upper portion of a groove having a recess shape” refers to a portion of the groove having a recess shape positioned at an opposite side to a bottom (for example, in FIG. 10, a surface contact with capacitive contact pad 10) of the groove in an extending direction of the groove (for example, in FIG. 10, direction 45).

Moreover, “an upper portion of a first electrode” refers to a portion of the first electrode positioned at an opposite side to a bottom (for example, in FIG. 10, a surface contact with capacitive contact pad 10) of the first electrode in an extending direction of the first electrode (for example, in FIG. 10, direction 45).

The invention will be now described herein with reference to illustrative embodiments. Those skilled in the art will recognize that many alternative //embodiments can be accomplished using the teachings of the present invention and that the invention is not limited to the embodiments illustrated for explanatory purpose.

In addition, the exemplary embodiments below will be explained by dividing them into a plurality of sections or embodiments if necessary for convenience. They should not be construed as not being related to one another, and are in relations of modified embodiments of parts or the entirety thereof, detailed explanation, and supplemental explanations, etc., unless otherwise expressly described herein.

### First Exemplary Embodiment

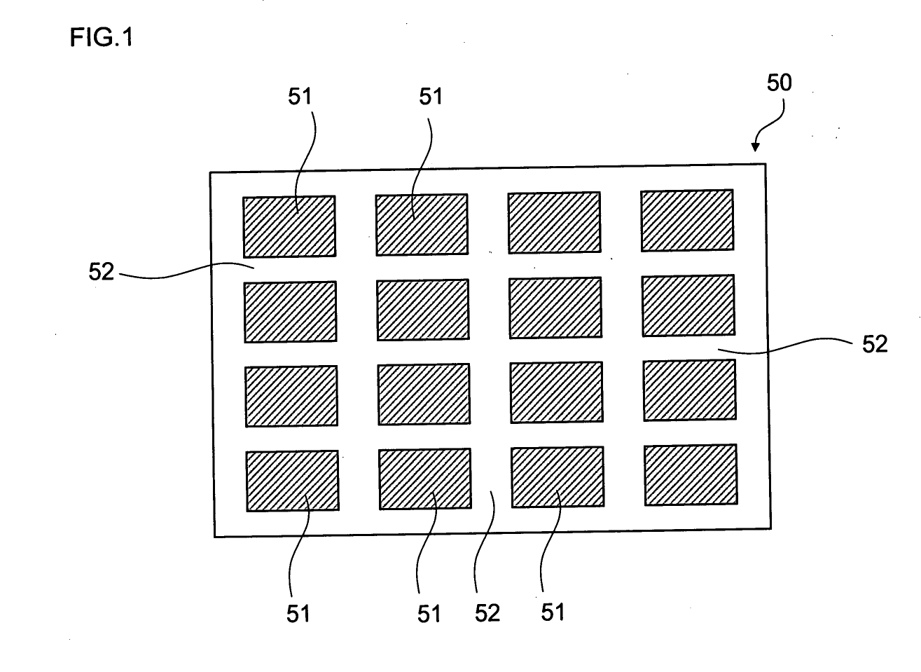

A DRAM device (chip) according to the semiconductor device of this exemplary embodiment schematically includes a memory cell region and a peripheral circuit region. FIG. 1 is a conceptional view of a plan structure of the DRAM device. DRAM device 50 includes a plurality of memory cell regions 51 and peripheral circuit region 52 surrounding each of the plurality of memory cell regions 51. Peripheral circuit region 52 includes a sense amplifier circuit, a circuit for driving a word line, input and output circuits from/to an external, etc. The layout in FIG. 1 is merely one example, and, thus, a number and an arrangement of the memory cell regions are not limited to the layout in FIG. 1.

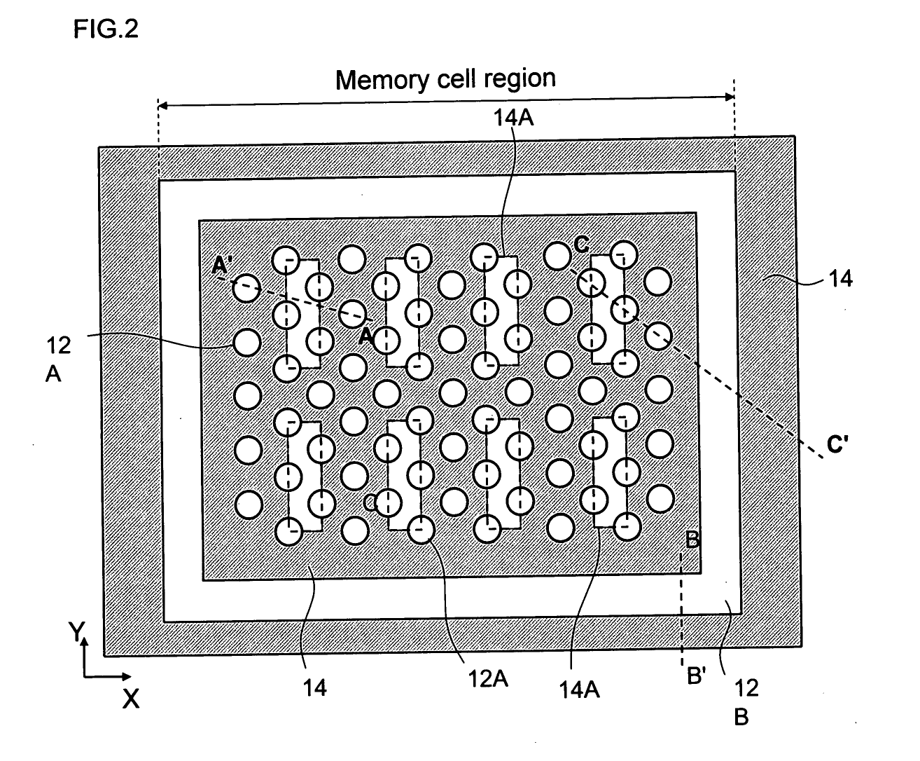

FIG. 2 is a conceptional view of a plan structure of an entirety of one memory cell region 51, and FIG. 2 shows only some components constituting the memory cell region. Guard ring 12B is disposed in an outer periphery of memory cell region 51 so as to surround the memory cell region. In this specification, “a memory cell region” is defined as a combination of guard ring 12B and an inner region surrounded with guard ring 12B. “A peripheral circuit region” is defined as a region outside of guard ring 12B. Meanwhile, in this exemplary embodiment, the inner region surrounded with guard ring 12B corresponds to a first region, and the region outside of guard ring 12B corresponds to a second region.

In FIG. 2, reference numeral 12A refers to a position of a lower electrode (first electrode) of a capacitor constituting one memory cell. Reference numeral 14 refers to a supporting film (supporting film) for preventing the lower electrode from falling down during the manufacturing process. Openings 14A are formed in supporting film 14 so as to be spaced from each other in a predetermined distance. Supporting film 14 is formed in the inner region surrounded with guard ring 12B, and, further, supporting film 14 with a predetermined width is formed in the region outside of guard ring 12B.

After the supporting film has been used according to its existing purpose during the manufacturing process, the supporting film is preferably patterned in peripheral circuit region 52 so that the supporting film remains only in a region with a predetermined width from guard ring 12B and is preferably removed in the other region than the region with the predetermined width. The reason why such patterning of the supporting film in peripheral circuit region 52 is carried out will be explained later. Meanwhile, the layouts of the capacitors and openings 14A in FIG. 2 are merely one example, and, thus, a number, shapes and arrangements of the capacitors and the openings are not limited to the layout in FIG. 2.

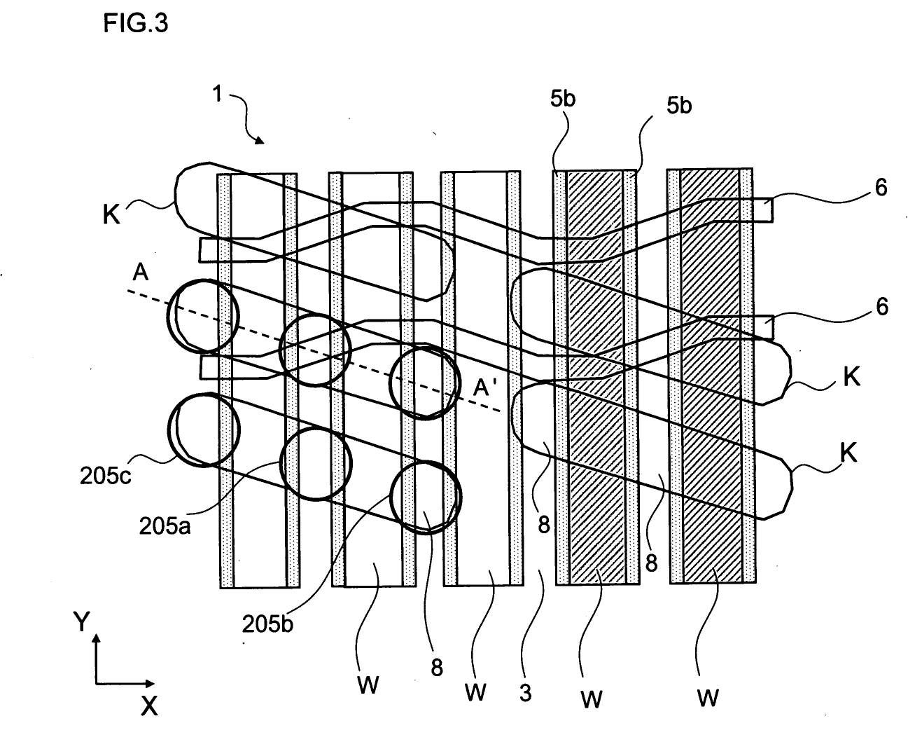

In the memory cell region, a plurality of memory cells are arranged according to a predetermined rule. FIG. 3 is a conceptional view of a plan structure of one memory cell, and FIG. 3 shows only some components constituting the memory cell are shown. A right area of FIG. 3 shows a transmission view of a plane cutting gate electrodes 5 being word wires W and side walls 5b thereof as will be explained later. A capacitor is not shown in the plan view of FIG. 3, but will be shown in a following cross-sectional view.

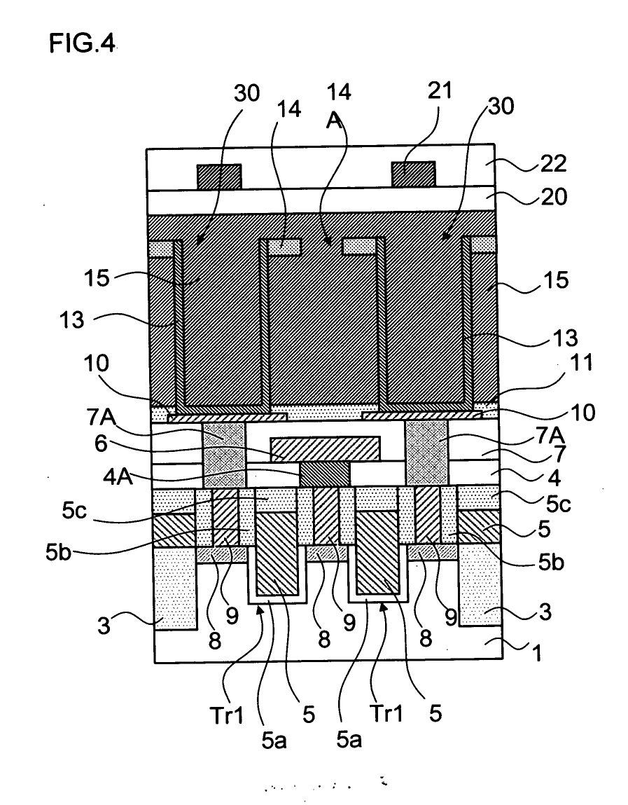

FIG. 4 is a schematic view of a cross section taken at a line A-A′ in FIG. 2 or 3. Those views are provided only to illustrate the configuration of the semiconductor device, and, thus, sizes or dimensions of the features in those views may be different from those of a real semiconductor device. As shown in FIG. 4, each memory cell schematically includes MOS transistors Tr1 for memory cell and capacitors 30 connected through a plurality of contact plugs to MOS transistors Tr1.

In FIG. 4, semiconductor substrate 1 is made of silicon containing P type impurities with a given concentration. Isolation regions 3 are formed in semiconductor substrate 1. Isolation regions 3 are formed in regions other than active region K by burying an insulating film such as a silicon oxide film (SiO₂) in the surface of semiconductor substrate 1 using a STI (Shallow Trench Isolation) technique, and isolates, in an insulating manner, corresponding active region K from adjacent active regions K. This exemplary embodiment illustrates one example in which the invention is applied to the cell structure where 2 bit memory cell is disposed in one active region K.

In this exemplary embodiment, as shown in FIG. 3, a plurality of elongate rectangular strip-like active regions K are arranged so as to tilt downwards in a right direction and to be spaced from each other in a predetermined distance. Impurity diffusion layers are formed at both end regions and a center region of each active region K respectively and serve as source and drain regions of MOS transistor Trl. Positions 205a, 205b, 205c of substrate contact plugs are defined so as to be disposed directly on the source and drain regions (the impurity diffusion layers) respectively. Meanwhile, the arrangement of active regions K is not limited to that as in FIG. 3. The active regions K may have an active region shape applied to general transistors other than that in this exemplary embodiment.

A plurality of bit lines 6 extend in a curved line shape (in a bended line shape) and in a lateral (X) direction of FIG. 3, and are arranged in a vertical (Y) direction of FIG. 3 so as to be spaced from each other in a given distance. A plurality of word wires W extend in a straight line shape and in the vertical (Y) direction of FIG. 3, and are arranged in the lateral (X) direction of FIG. 3 so as to be spaced from each other in a given distance. Each of a plurality of word wires W is configured in such a way as to include gate electrode 5 as shown in FIG. 4 at an intersecting point between each word line W and each active region K. This exemplary embodiment illustrates one example in which MOS transistor Trl includes a gate electrode with a groove shape. Instead of MOS transistor with such a gate electrode with a groove shape, there may be employed a planar type MOS transistor or a MOS transistor with a channel region formed at a side surface of a groove formed in the semiconductor substrate. Moreover, a vertical MOS transistor with a pillar shape channel region may be used.

As shown in the cross-sectional structure of FIG. 4, in semiconductor substrate 1, impurity diffusion layers 8 functioning as the source and drain regions are formed in active regions K partitioned with isolation region 3 so as to be spaced from each other. Gate electrodes 5 having the groove shape are formed between impurity diffusion layers 8. Gate electrodes 5 are made of a stack of a polysilicon film and a metal film so as to protrude from the surface of semiconductor substrate 1. Here, the polysilicon film containing impurities such as phosphorus therein may be formed in forming the film using a CVD (chemical vapor deposition) method. Otherwise, after forming the polysilicon film not containing the impurities, N type or P type impurities may be implanted into the polysilicon film using an ion-implanting method in a following separate process. The metal film used for the gate electrode may include refractory metal such as tungsten (W), nitride tungsten (WN) or tungsten silicide (WSi).

Gate insulating films 5a are formed between gate electrodes 5 and semiconductor substrate 1. Sidewalls 5b made of insulating films such as nitride silicon (Si₃N₄) films are formed on the side walls of gate electrodes 5, and, also, insulating films 5c such as the nitride silicon (Si₃N₄) films are formed on top surfaces of gate electrodes 5 in order to protect it.

Impurity diffusion layers 8 are formed by implanting into semiconductor substrate 1, for example, phosphorus as N type impurities. Gate interlayer insulating film (not shown in FIG. 4) made of silicon oxide is formed to fill the spaces between the gate electrodes. Substrate contact plugs 9 are formed so as to be in contact with impurity diffusion layers 8. Substrate contact plugs 9 are placed at positions 205a, 205b and 205c in FIG. 3 respectively and are made of polysilicon containing, for example, phosphorus. Lateral (X) widths of substrate contact plugs 9 are defined by side walls 5b formed on adjacent word wires W, that is, substrate contact plugs 9 are made in a self-aligned manner.

First interlayer insulating film 4 is formed to cover insulating films 5c on the gate electrode and substrate contact plugs 9, and bit line contact plug 4A is formed so as to penetrate through first interlayer insulating film 4. Bit line contact plug 4A is disposed at position 205a of one substrate contact plug and is electrically connected to the corresponding substrate contact plug 9. Bit line contact plug 4A is formed as a stacked structure in which a tungsten (W) film is stacked on a barrier film (TiN/Ti) made of a stack of a titanium film and a titanium nitride film. Bit wire 6 is formed so as to be connected to bit line contact plug 4A. Bit wire 6 is made of a stacked structure in which a nitride tungsten film is deposited on a tungsten film.

Second interlayer insulating film 7 is formed to cover bit wire 6. Capacitive contact plugs 7A are formed so as to penetrate through first and second interlayer insulating films 4, 7 and then to be connected to two other substrate contact plugs 9 respectively. Capacitive contact plugs 7A are placed at positions 205b, and 205c of two other substrate contact plugs.

Capacitive contact pads 10 are formed on second interlayer insulating film 7 and are electrically connected to capacitive contact plugs 7A respectively. Capacitive contact pads 10 are made of a stacked structure in which a nitride tungsten film is deposited on a tungsten film. Third interlayer insulating film 11 made of nitride silicon is formed to cover capacitive contact pads 10. Capacitors 30 are formed to be connected to capacitive contact pads 10 respectively.

In capacitors 30, capacitive insulating films (not shown in FIG. 4) are sandwiched between lower electrodes 13 (first electrodes) and upper electrodes 15 (second electrodes), and lower electrodes 13 are connected to capacitive contact pads 10 respectively. Supporting films 14 are formed to support the upper ends of lower electrodes 13 so that the lower electrodes are prevented from collapsing during the manufacturing process by the supporting films 14.

Fifth interlayer insulating film 20 is formed on capacitors 30, and upper metal interconnection layers 21 made of aluminum (Al) and copper (Cu) are formed on fifth interlayer insulating film 20, and surface protection film 22 is formed on the entire surface of the resultant structure.

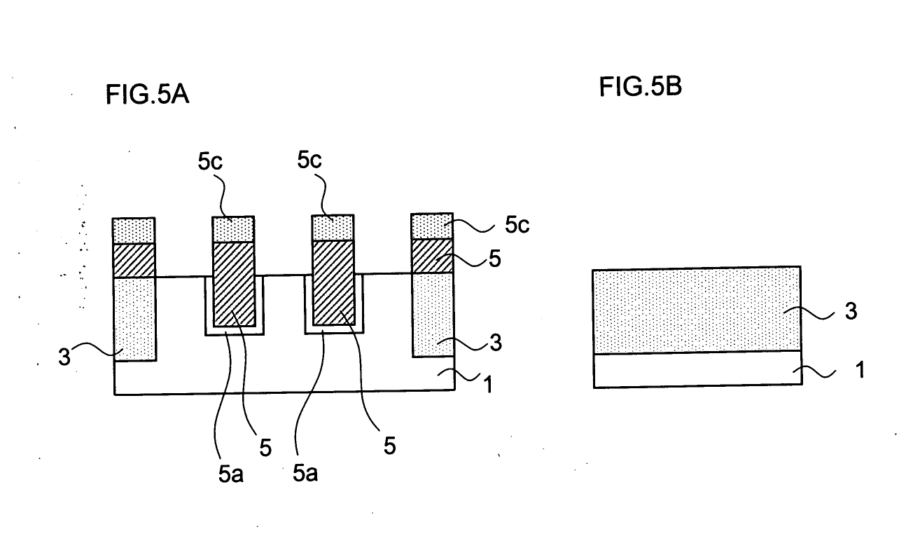

Now, the method for manufacturing the semiconductor device according to this exemplary embodiment will be described. First, processes taken until forming third interlayer insulating film 11 covering capacitive contact pads 10 will be explained with reference to FIG. 5 to FIG. 7.

In these figures, figures represent by a character “A” are ones corresponding to schematic cross-sectional views taken at a line A-A′ of each memory cell in FIG. 3, and figures represent by a character “B” are ones corresponding to schematic cross-sectional views taken at a line B-B′ in the outer periphery of the memory cell region and the region outside of the guard ring in FIG. 2. Meanwhile, although not mentioned in a particular way, it is noted that below, the manufacturing process of the each memory cell and the manufacturing process of the outer periphery of the memory cell region and the region outside of the guard ring will be explained at the same time with reference to figures by a character “A” and “B”.

As shown in FIG. 5, isolation regions 3 for partitioning active regions K were formed in regions other than active regions K by burying an insulating film such as a silicon oxide film (SiO₂) in the main surface of semiconductor substrate 1 made of P type silicon using a STI (Shallow Trench Isolation) technique. Next, a grooves pattern for the gate electrodes of MOS transistors Trl was formed in semiconductor substrate 1, and the silicon surface of semiconductor substrate 1 was subjected to a thermal oxidization method so as to turn into the silicon oxide, resulting in forming gate insulating films 5a with 4 nm in the transistor formation regions. A stack of a silicon oxide film and a nitride silicon film or a high-K film (high dielectric film) may be employed as the gate insulating films.

Thereafter, a polysilicon film containing N type impurities was deposited on gate insulating films 5a by performing a CVD method using monosilane(SiH₄) and phosphine(PH₃) as source gas. At this time, the deposited film thickness was set to fill fully inner spaces of the grooves for the gate electrodes with the polysilicon film. Otherwise, after forming the polysilicon film not containing the impurities, N type or P type impurities may be implanted into the polysilicon film using an ion-implanting method in a subsequent process. Next, a metal film made of refractory metal such as tungsten silicide, nitride tungsten or tungsten was deposited with 50 nm thickness on the polysilicon film using a sputtering method. A stack of the polysilicon film and metal film were formed as gate electrodes 5 using the process as will be described later.

That is, insulating film 5c made of nitride silicon was deposited with 70 nm thickness on the metal film constituting gate electrodes 5 using a plasma CVD method. Gate electrodes 5 were formed by patterning sequentially insulating film 5c, the metal film and the polysilicon film. Gate electrodes 5 serve as word lines W (FIG. 3).

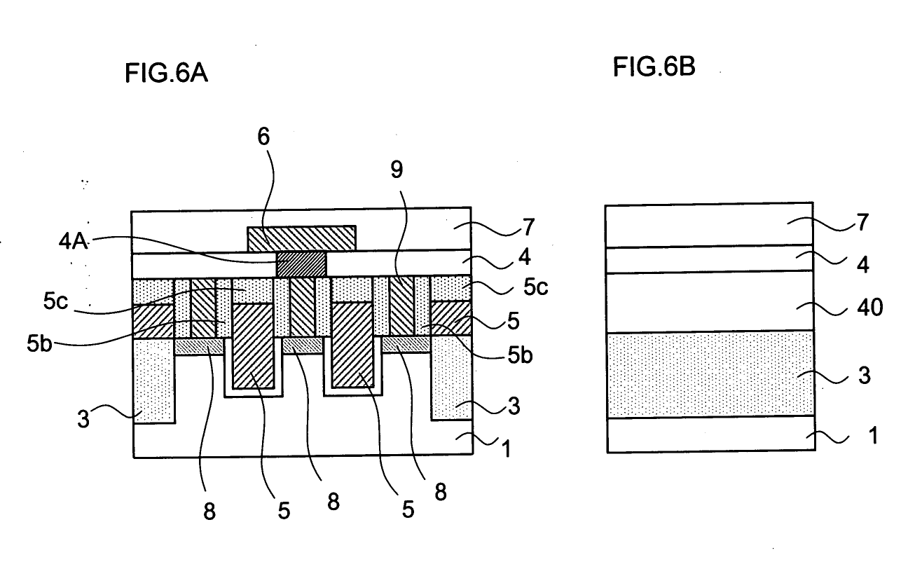

Then, as shown in FIG. 6, phosphorus as N type impurities was implanted into the surface of the semiconductor substrate using an ion-implanting method, resulting in forming impurities diffusion layers 8 in the portions of the active region on which gate electrodes 5 were not formed. Subsequently, a nitride silicon film with 20 to 50 mm thickness was formed on the entire surface of resulting structure using a CVD method. Then, the nitride silicon film was etched back to form side walls 5b on the side walls of gate electrodes 5.

Next, gate interlayer insulating film 40 (not shown in FIG. 6A) made of silicon oxide was formed using a CVD method so as to cover insulating films 5c on the gate electrodes and side walls 5b on the side walls of the gate electrodes. Using a CMP (chemical mechanical polishing) method, an uneven surface resulting from gate electrodes 5 is polished and planarized. Such a polishing was stopped at the time when the top surfaces of insulating films 5c on the gate electrodes were exposed. Then, substrate contact plugs 9 were formed.

Speaking specifically about the formation of the substrate contact plugs, first, etching was carried out using a photoresist pattern as a mask so that openings were formed at positions 205a, 205b, and 205c in FIG. 3 of the substrate contact plugs. Next, already-formed gate interlayer insulating film 40 was removed, and, hence, the surface of semiconductor substrate 1 was exposed. The openings can be formed between gate electrodes 5 in a self-alignment manner by making use of insulating films 5c, 5b made of the nitride silicon. The polysilicon film containing phosphorus was deposited into the openings using a CVD method. Thereafter, using a CMP method, the polysilicon film on insulating films 5c was polished and removed away, thereby forming substrate contact plugs 9 buried into the openings.

Using a CVD method, first interlayer insulating film 4 made of silicon oxide was formed with, for example, 600 nm thickness so as to cover substrate contact plugs 9 and insulating films 5c on the gate electrodes. Using a CMP method, the surface of first interlayer insulating film 4 was polished and planarized until a thickness of first interlayer insulating film 4 becomes for example 300 nm.

As shown in FIG. 6, openings (contact holes) were formed at positions 205a in FIG. 3 of the substrate contact plug so as to penetrate through first interlayer insulating film 4, resulting in exposing central substrate contact plugs 9. The barrier films such as TiN/Ti were deposited and a tungsten (W) films were deposited on the barrier films so that they completely filled the opening and, then, the surfaces thereof were polished with a CMP method, to form Bit line contact plug 4A.

Thereafter, bit line 6 made of a stack of a nitride tungsten film and a tungsten film was formed so as to be connected to bit line contact plug 4A.

Second interlayer insulating film 7 made of silicon oxide film was formed to cover bit line 6.

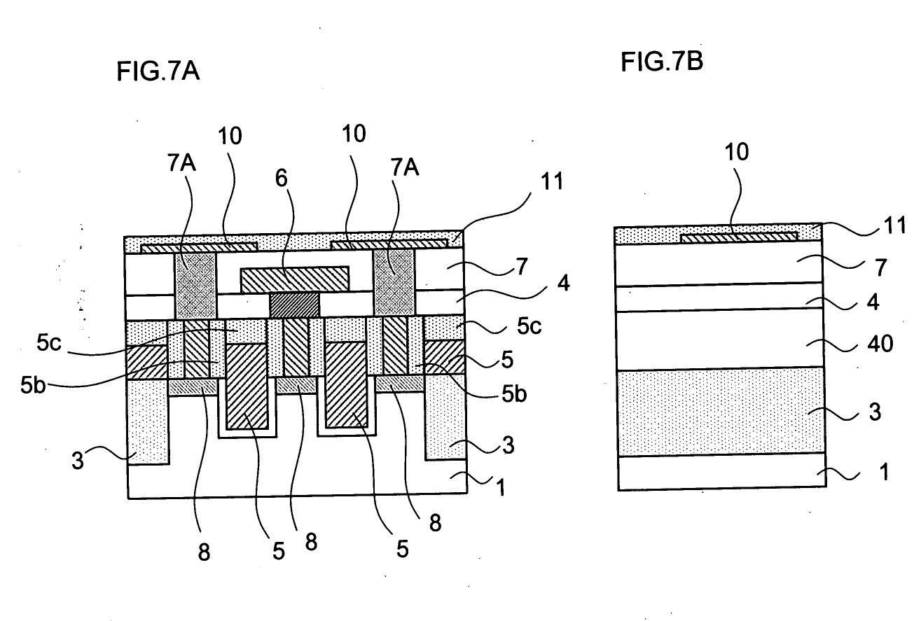

Next, as shown in FIG. 7, openings (contact holes) were formed at positions 205b, 205c in FIG. 3 of the two other substrate contact plugs so as to penetrate through first and second interlayer insulating films 4, 7, resulting in exposing the two substrate contact plugs 9. The barrier films such as TiN/Ti were deposited and a tungsten (W) films were deposited on the barrier films so that they completely fill the openings and, then, the surfaces thereof were polished with a CMP method, to form capacitive contact plugs 7A. Capacitive contact pads 10 made of a stack of a nitride tungsten film and a tungsten film were formed on second interlayer insulating film 7. Capacitive contact pads 10 were electrically connected to capacitive contact plugs 7A respectively, and the widths of capacitive contact pads 10 were set to become larger than the widths of the bottoms of the lower electrodes of the capacitors to be formed later. As shown FIG. 7B, in the outer periphery of the memory cell region and the region outside of the guard ring, capacitive contact pad 10 was formed. This capacitive contact pad 10 formed in FIG. 7B was placed at region to be formed groove 12B having the recess shape as shown in FIG. 2.

Third interlayer insulating film 11 made of nitride silicon was deposited with, for example, 60 nm thickness so as to cover capacitive contact pads 10. Third interlayer insulating film 11 serves as a stopper film against the chemical solution used in wet etching as will be described later.

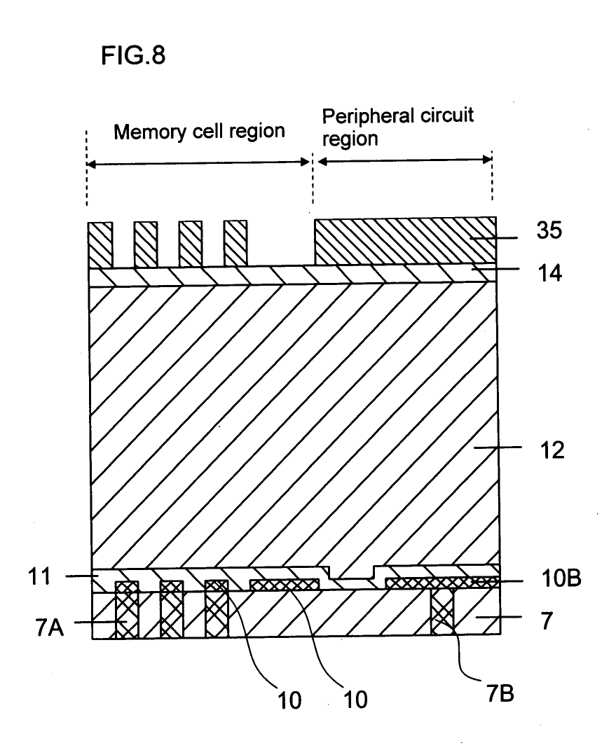

Subsequent processes will be described with reference to figures corresponding to cross-sectional views (FIG. 8 to FIG. 16) taken at a line C-C′ in FIG. 2. In those cross-sectional views, for the sake of clarification, only more upper portions than the bit line are shown.

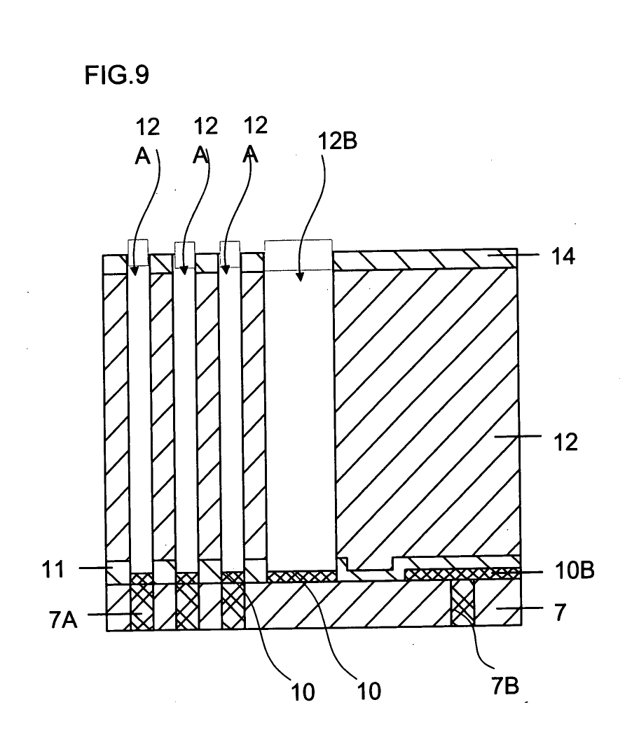

In FIG. 8, a left section is the memory cell region and a right section is the peripheral circuit region (the same holds for FIG. 9 to FIG. 16).

Capacitive contact plugs 7A and capacitive contact pads 10 were formed as described with reference to FIG. 7. In the peripheral circuit region, interconnection layer 10B was formed by patterning the same layer as the capacitive contact pads. Interconnection layer 10B was connected through contact plug 7B to the underlying impurities diffusion layer or gate electrode. Contact plug 7B may be formed at the same time as in forming capacitive contact plugs 7A. A hole with a desired depth may be formed by overetching a contact hole for the contact plug. Fourth interlayer insulating film 12 made of silicon oxide was deposited with, for example, 2 μm thickness. Supporting film 14 made of nitride silicon was deposited with 50 nm thickness on fourth interlayer insulating film 12 using a hot-wall type LP CVD (low-pressure chemical vapor deposition) method or a ALD (atomic layer deposition) method. Photoresist mask pattern 35 was formed on supporting film 14. Mask pattern 35 has openings at positions corresponding to lower electrode formation positions 12A in the capacitors and groove formation position 12B surrounding the memory cell region.

As shown in FIG. 9, anisotropic etching was performed using mask pattern 35, to form elongate openings which penetrate through supporting film 14, fourth interlayer insulating film 12, and third interlayer insulating film 11. In this manner, openings 12A used in forming the lower electrodes of the capacitors and groove 12B having the recess shape surrounding the memory cell region were simultaneously formed, resulting in exposing the top surfaces of capacitive contact pads 10. After forming openings 12A and groove 12B having the recess shape, mask pattern 35 was removed.

As shown in FIG. 10, titanium nitride (TiN) film 13 as a conductive film for forming the lower electrodes was formed with about 20 nm thickness using a CVD method. Titanium nitride (TiN) film 13 (corresponding to a first film) was formed so as to cover inner walls of openings 12A and groove 12B having the recess shape.

Next, using a film forming method resulting in bad step coverage, first silicon nitride film 31 (corresponding to a fifth film) was formed with about 50 nm thickness. Speaking specifically, using a parallel plate type PE-CVD (Plasma Enhanced CVD) method (which, hereinafter, will be referred to as “a plasma CVD method”), first silicon nitride film 31 was formed. When formed using the plasma CVD method, the silicon nitride film may be formed at 500° C. or a lower temperature than 500° C., but, in this case, since many of hydrogen atoms in source gas remain in the formed film, only the film with poor resistance to hydrofluoric acid is formed. Therefore, when the film is exposed to the hydrofluoric acid for a long time, the film disappears. Moreover, it is known that the formed film has a bad coverage. In this exemplary embodiment, first silicon nitride film 31 was used as a cap film for blocking openings 12A.

In this exemplary embodiment, first silicon nitride film 31 was deposited by performing the plasma CVD method using SiH₄ gas and NH₃ gas as source gas. In case that the layout of the memory cell is based on the design rule finer than a design rule 60 nm, the diameters of openings 12A for forming the lower electrodes become smaller than or equal to approximately 100 nm. When the silicon nitride film was deposited at the openings with such very fine diameters using the plasma CVD method resulting in the bad step coverage, upper ends of the openings were blocked with the deposited film thereto, and, thus, the silicon nitride film was scarcely deposited in the inner walls of the openings.

Further, in advance, a width L of the aperture of the groove 12B having the recess shape was set to become slightly larger than the diameters of openings 12A (for example, the width of the aperture of the groove 12B is 1.2 to 1.8 times as large as the diameters of openings) so that the upper aperture of the groove 12B was not blocked with deposited first silicon nitride film 31. Moreover, such blocking occurs with lower probability than in the groove having the recess shape extending far away in a given direction, compared to in holes having substantially circular apertures. Accordingly, the width of the groove may be set in a consideration of such fact.

Although the upper aperture of groove 12B having the recess shape was not blocked with the first silicon nitride film 31, the first silicon nitride film was deposited thickly around the upper aperture of the groove. Moreover, the silicon nitride film was scarcely deposited on the inner side walls of groove 12B other than around the upper aperture. Finally, the first silicon nitride film 31 is formed in the groove 12B so that a size-reduced upper aperture recesses in the central region of the upper aperture width of the groove 12B.

Next, using a film forming method resulting in superior step coverage, second silicon nitride film 32 (corresponding to a second film) was formed with about 50 nm thickness. To be specific, second silicon nitride film 32 was deposited using a hot-wall type LP-CVD (which, hereinafter, will be referred to as “a LP-CVD method') using SiH₂Cl₂ gas and NH₃ gas as source gas.

The LP-CVD method is a film forming method in which the source gas is subjected to thermal reaction at the temperature of 650 to 800° C. so as to be deposited as the film, and produces the silicon nitride film with superior resistance to the hydrofluoric acid. Moreover, it is known that the formed silicon nitride film has a superior coverage. Accordingly, it is easy to cover the inner walls of the groove having silicon nitride film through the remaining upper aperture.

Second silicon nitride film 32 covered the top surface of first silicon nitride film 31, and, at the same time, invaded the inner space within groove 12B having the recess shape through the remaining upper aperture of the groove, resulting in covering the inner wall of groove 12B having the recess shape. At this time, cavity 33 surrounded with the second silicon nitride film may remain in the groove having the recess shape. In this exemplary embodiment, since first silicon nitride film 31 was formed at earlier time than second silicon nitride film 32, second silicon nitride film 32 was not formed in the openings 12A for forming the lower electrodes. On the other hand, since the upper aperture of groove 12B for guard ring was not blocked with first silicon nitride film 31, second silicon nitride film 32 was formed so as to cover the inner wall of groove 12B having the recess shape.

Thereafter, a mask pattern was formed using photoresist film 34. Photoresist film 34 had a pattern with openings at the positions corresponding to openings 14A in FIG. 2 in the memory cell region.

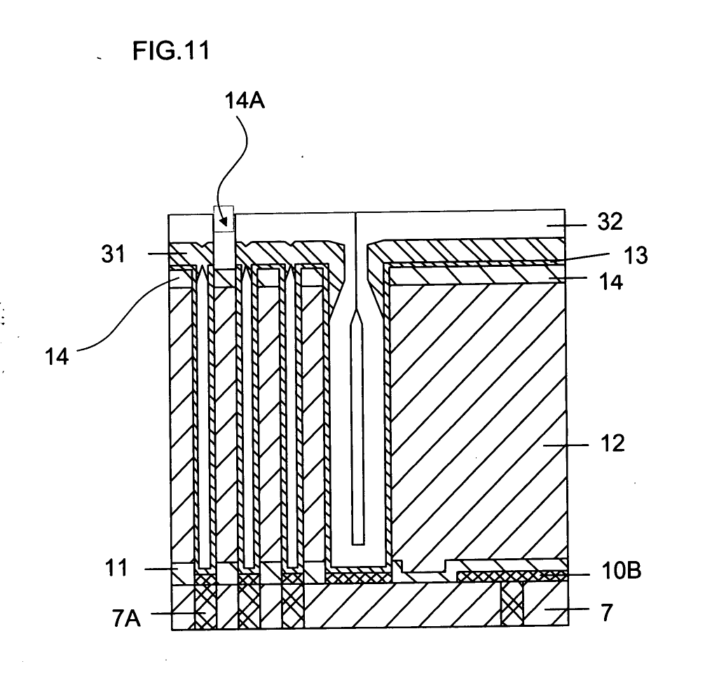

As shown in FIG. 11, second silicon nitride film 32, first silicon nitride 31, and titanium nitride film 13 were sequentially removed at the position corresponding to opening 14A by performing dry etching using patterned photoresist 34 as a mask. After the etching, patterned photoresist 34 was removed.

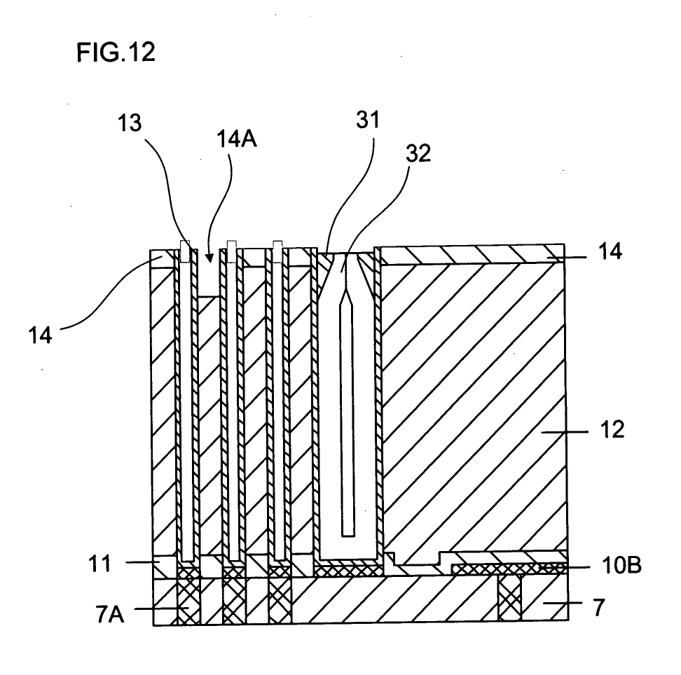

As shown in FIG. 12, the silicon nitride film 13 was etched back to expose the upper surfaces of titanium nitride films 13. At this time, seeing that supporting film 14 made of the silicon nitride was already exposed at the position corresponding to opening 14A (in a region at which titanium nitride film 13 had been already removed in the process in FIG. 11). Therefore, an etching proceeded at the same time as in the etching-back so that opening 14A was formed so as to penetrate through supporting film 14 in the region at which titanium nitride film 13 had been already removed. At this time, it is not problematic that fourth interlayer insulating film 12 in the opening 14A is more or less etched away. The etching-back was stopped at the time when the upper surfaces of titanium nitride films 13 began to be exposed so that first and second silicon nitride films 31, 32 remained within groove 12B having the recess shape.

Subsequently, titanium nitride films 13 were etched back to remove the titanium nitride films 13 exposed on supporting film 14 so that titanium nitride films 13 remained on the side inner walls of openings 12A and groove 12B having the recess shape. At this time, in case aspect ratios of openings 12A are sufficiently large,since titanium nitride films 13 at the bottoms of openings 12A are not etched away, titanium nitride films 13 at the bottoms of openings 12A can remain without suffering the damage.

Optionally, the etching-back may be carried out while openings 12A are filled with a photoresist film and titanium nitride films 13 at the bottoms of openings 12A are protected with the photoresist film. Then, the filled photoresist film may be removed.

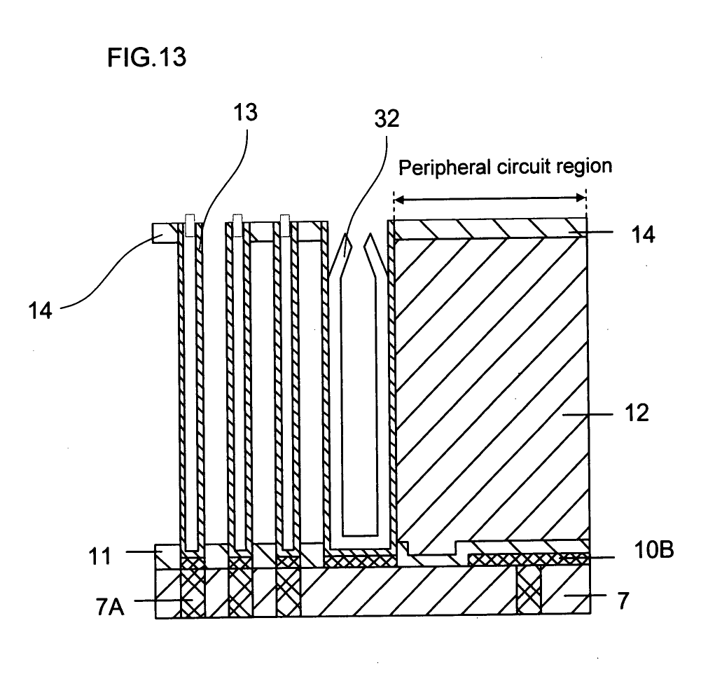

As shown in FIG. 13, fourth interlayer insulating film 12 in the memory cell region was selectively removed by performing wet etching using the diluted hydrofluoric acid, resulting in exposing the outer walls of titanium nitride films 13 in openings 12A. In this way, the lower electrodes of the capacitors made of titanium nitride films 13 were formed at the positions of openings 12A.

Third interlayer insulating film 11 made of the silicon nitride film functions as a stopper film during the wet etching, and, thus, prevents the etchant from invading the underlying portions thereof. As shown in FIG. 12, an upper portion of groove 12B having the recess shape is completely blocked with first and second silicon nitride films 31, 32. Titanium nitride film 13 on an inner side wall of the upper portion of groove 12B having the recess shape is covered with first and second silicon nitride films 31, 32. For this reason, during the wet etching, the etchant is prevented from invading the peripheral circuit region through groove 12B having the recess shape.

Further, supporting film 14 made of the silicon nitride film covers the entire surface of the peripheral circuit region. For this reason, during the wet etching, the etchant is prevented from invading the peripheral circuit region.

Meanwhile, first silicon nitride film 31 formed using the plasma CVD method has poor resistance to the diluted hydrofluoric acid as compared to second silicon nitride film 32 formed using the LP-CVD method. Accordingly, in case that the formed films are exposed to the etchant used in the wet etching for a long time, first silicon nitride film 31 in groove 12B having the recess shape is finally removed and second silicon nitride film 32 remains in groove 12B having the recess shape. In this case, since the remaining second silicon nitride film 32 can extend the time till when the etchant reaches titanium nitride film 13 in groove 12B having the recess shape, thereby suppressing the invasion of the etchant into the peripheral circuit region.

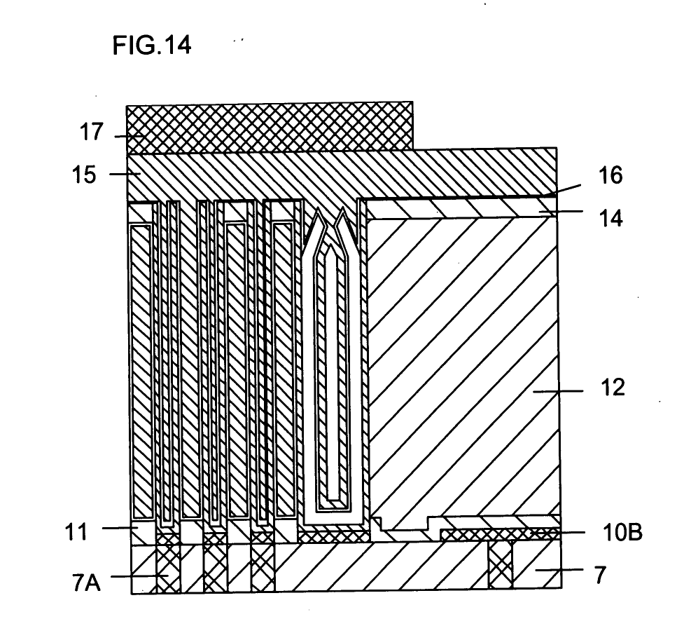

As shown in FIG. 14, capacitive insulating films 16 (corresponding to a third film) were formed on the surfaces of titanium nitride films (lower electrodes) 13. Thereafter, upper electrode (plate electrode) 15 made of a titanium nitride film was formed. Since second silicon nitride film 32 was not formed in openings 12A, capacitive insulating films 16 were interposed between lower electrodes 13 and upper electrode 15, thereby producing the capacitors. A high dielectric film such as a zirconium oxide (ZrO₂) film or an aluminum oxide (Al₂O₃) film or a hafnium oxide (HfO₂) film or a stack of those films may be used as the capacitive insulating films. The upper electrode may include a stacked structure in which a titanium nitride film is formed with about 10 nm thickness, and a polysilicon film doped with impurities is formed on the titanium nitride film, so that the cavities between neighboring lower electrodes are fully filled with the two films, and then a tungsten film with about 100 nm thickness is formed on the entire surface of the resultant structure. Meanwhile, groove 12B having the recess shape is provided to prevent the chemical solution used in the etching from invading the peripheral circuit region and does not function as the capacitor. Therefore, it is not problematic that second silicon nitride film 32 remains in groove 12B having the recess shape. Next, in order to pattern the upper electrode, a mask pattern made of photoresist 17 was formed.

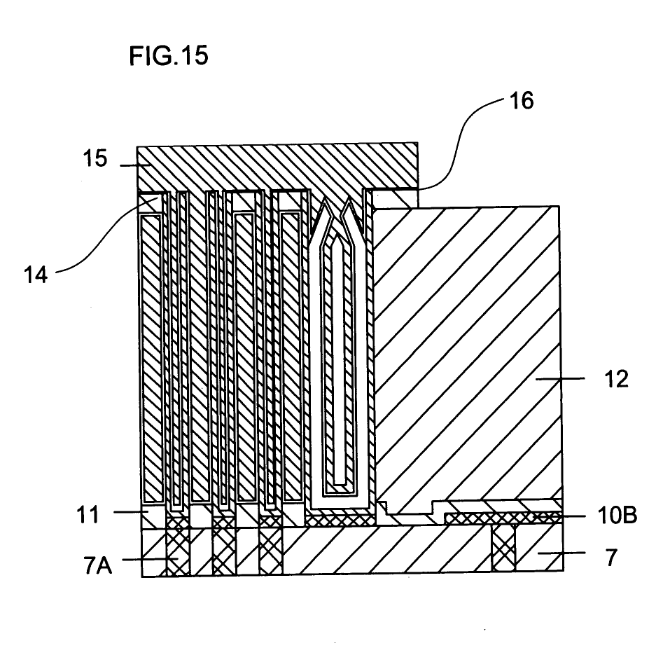

As shown in FIG. 15, unnecessary films (upper electrode 15, capacitive insulating film 16 and supporting film 14) on the peripheral circuit region were removed by performing dry etching using photoresist 17 as a mask. After the etching, photoresist 17 was removed.

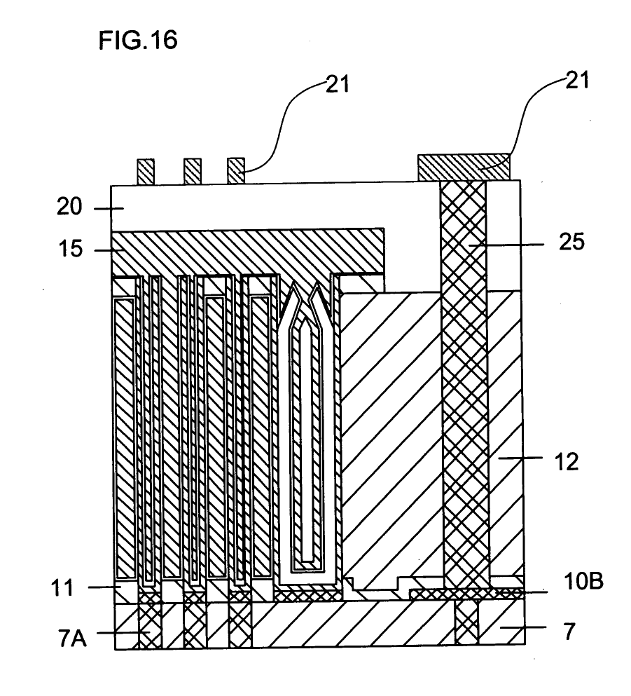

As shown in FIG. 16, fifth interlayer insulating film 20 covered upper electrodes 15, and, then, fifth interlayer insulating film 20 was planarized using a CMP method. In the peripheral circuit region, contact plug 25 was formed which reached interconnection layer 10B, and the upper metal interconnection layer 21 was formed on contact plug 25. As shown in FIG. 15, since supporting film 14 remaining on the peripheral circuit region had, in advance, been removed, it is easy to form a deep contact hole reaching interconnection layer 10B using the dry etching.

A tungsten film may be used as contact plug 25. Aluminum (Al) or copper (Cu) may be used as metal interconnection layer 21. A metal interconnection layer and a contact plug connected to a circuit for supplying a given voltage to upper electrode 15 may be formed in a region as not shown. The contact plug connected to the upper electrode and contact plug 25 provided in the peripheral circuit region may be simultaneously formed. Thereafter, surface protection film 22 in FIG. 4 was formed, thereby completing the DRAM device.

In the semiconductor device according to this exemplary embodiment, the capacitors using as the electrodes both of the outer and inner walls of the cylindrical lower electrodes were formed in the memory cell region of the DRAM device. At this time, the second silicon nitride film was not formed in the capacitors. The guard ring prevents the etchant or chemical solution used in the wet etching process for exposing the outer walls of the capacitor from invading the peripheral circuit region. In this way, although a semiconductor device miniaturizes, it is easy to manufacture the capacitor with large capacitance. Consequently, it is possible to manufacture a highly integrated DRAM device with excellent refreshing characteristics.

### Second Exemplary Embodiment

This exemplary embodiment is directed to a method for forming second silicon nitride 32 covering the inner wall of groove 12B with good coverage. This exemplary embodiment is different from the first exemplary embodiment in that this exemplary embodiment employs an ALD (atomic layer deposition) method, instead of the LP-CVD method used in the first exemplary embodiment.

When using the ALD method, SiH₂Cl₂ gas and NH₃ gas are used as source gas, and the structure on the semiconductor substrate whose temperature is set to 500 to 550° C. is subjected to alternate repetitions of a first step of supplying SiH₂Cl₂ gas and purging SiH₂Cl₂ gas by nitrogen gas and a second step of supplying NH₃ gas and purging NH₃ gas by nitrogen gas, thereby depositing the silicon nitride film with a desired film thickness and with the good coverage. Also, since the formed silicon nitride film using the ALD method has good resistance to hydrofluoric acid, the silicon nitride film prevents the etchant from invading the peripheral circuit region beyond the guard ring.

It is apparent that the present invention is not limited to the above embodiments, but may be modified and changed without departing from the scope and spirit of the invention.

What is claimed is:

1. A semiconductor device, comprising:
a first region;
a guard ring surrounding the first region; and
a second region outside of the guard ring,
wherein the first region comprises a first electrode made of a first film which has conductivity,
wherein the guard ring comprises the first film covering an inner wall of a groove having a recess shape, and a second film as an insulating film covering at least one portion of a surface of the first film in the groove, and
wherein a surface of the first electrode in the first region is not covered with the second film.

2. The semiconductor device according to claim 1,
wherein in the guard ring, the second film covers the first film on a bottom surface of the groove and on a side surface except a side surface of an upper portion of the groove and,
the second film is spaced from the first film on the side surface of the upper portion of the groove and is bent in an inner direction.

3. The semiconductor device according to claim 1,
wherein the first region further comprises:
a third film as an insulating film covering a surface of the first electrode; and
a second electrode made of a fourth film having conductivity and facing the first electrode with the third film interposed between the first electrode and the second electrode, and
wherein the guard ring further comprises:
the third film covering a surface of the second film; and
the fourth film which includes a portion facing the first film with the second and third films interposed between the first film and the fourth film.

4. The semiconductor device according to claim 1,
wherein the first region and the guard ring form a memory cell region,
the first and second electrodes and the third film form a capacitor,
the second region forms a peripheral circuit region, and
the semiconductor device is dynamic random access memory.

5. The semiconductor device according to claim 4,
wherein the memory cell region comprises a transistor and a bit line connected to one of source and drain regions of the transistor, and
the first electrode is connected to the other of the source and drain regions of the transistor.

6. The semiconductor device according to claim 1,
wherein the second film is a silicon nitride film.

7. A method for manufacturing a semiconductor device, comprising;
providing a structure comprising a semiconductor substrate, an interlayer insulating film, and a supporting film in this order, the structure including a first region, a second region surrounding the first region, and a boundary between the first and second regions;
forming a groove having a recess shape, the groove including an inner wall covered with a first film having conductivity, in the interlayer insulating film positioned in the boundary;
forming a fifth film as an insulating film in the first and second regions and the groove so that an upper portion of the groove is not blocked with the fifth film;
forming a second film as an insulating film in the first and second regions and the groove so as to cover a surface of the fifth film in the first and second regions and the groove and cover a surface of the first film exposed in the groove;
removing the second film so that the second film remains only in the groove; and
removing the interlayer insulating film in the first region using wet etching.

8. The method for manufacturing a semiconductor device according to claim 7,
wherein in forming the fifth film, the fifth film made of silicon nitride film is formed by using a parallel plate type plasma CVD method.

9. The method for manufacturing a semiconductor device according to claim 7,
wherein in forming the second film, the second film made of silicon nitride film is formed by using a hot-wall type LP-CVD method or an ALD method.

10. The method for manufacturing a semiconductor device according to claim 7,
wherein in forming the groove having the recess shape, a first electrode including a tubular inner wall made of the first film is formed in the first region, at the same time of forming the groove having the recess shape,
in forming the fifth film, the fifth film is formed so that an upper portion of the first electrode is blocked with the fifth film, and
in removing the interlayer insulating film in the first region, an outer side wall of the first electrode is exposed by using the wet etching.

11. The method for manufacturing a semiconductor device according to claim 10, further comprising forming an opening in the supporting film so that a portion of an outer side wall of the first electrode is sustained by the supporting film, between removing the second film and removing the interlayer insulating film in the first region,
wherein in removing the interlayer insulating film in the first region, the wet etching is performed using the supporting film which includes therein the opening as a mask.

12. The method for manufacturing a semiconductor device according to claim 10,
wherein in forming the groove having the recess shape, a width of the upper portion of the groove is set so that the upper portion of the groove is not blocked with the fifth film, and
an inner diameter of the upper portion of the first electrode is set so that the upper portion of the first electrode is blocked with the fifth film.

13. The method for manufacturing a semiconductor device according to claim 12,
wherein the width of the upper portion of the groove is 1.2 to 1.8 times larger than the inner diameter of the upper portion of the first electrode.

14. The method for manufacturing a semiconductor device according to claim 10, further comprising: after removing the interlayer insulating film in the first region,
forming a third film as an insulating film covering a surface of the first electrode; and
forming a fourth film having conductivity on the third film to form a second electrode facing the first electrode and made of the fourth film with the third film interposed between the first electrode and the second electrode.

15. The method for manufacturing a semiconductor device according to claim 14,
wherein in forming the third film, the third film is formed on the second film remaining in the groove, at the same time of forming the third film covering the surface of the first electrode, and
in forming the fourth film, the fourth film is formed in the groove, at the same time of forming the fourth film on the third film in the first region, the fourth film including a portion facing the first film with the second and third films interposed between the first film and the fourth film.

16. The method for manufacturing a semiconductor device according to claim 10,
wherein in providing the structure, the structure including a transistor is formed, and
in forming the groove having the recess shape, the first electrode is formed so that the first electrode is connected to a source region or drain region of the transistor.

17. The method for manufacturing a semiconductor device according to claim 7,
wherein in providing the structure, the supporting film made of silicon nitride film is formed using a hot-wall type LP-CVD method or an ALD method.

18. The method for manufacturing a semiconductor device according to claim 7,
wherein the removing of the second film comprises removing the second film and the fifth film in the first and second regions using dry etching.
